(19) United States
(12) Patent Application Publication
(10) Pub. No.: US 2022/0365125 A1
(43) Pub. Date: Nov. 17, 2022

(54) A COMMUTATION FAILURE PROTECTION METHOD, AND APPARATUS, COMPUTER DEVICE AND STORAGE MEDIUM THEREOF

(71) Applicant: South China University of Technology, Guangzhou City (CN)

(72) Inventors: Xiaohua Li, Guangzhou City (CN); Jiewen Li, Guangzhou City (CN); Shanshan Yin, Guangzhou City (CN)

(21) Appl. No.: 17/639,640

(22) PCT Filed: Jan. 15, 2021
(86) PCT No.: PCT/CN2021/071973

§ 371 Date: Mar. 2, 2022

(30) Foreign Application Priority Data
Jan. 19, 2020 (CN) 202010057252.3

(51) Int. Cl. G01R 31/08; H02H 7/26; H02H 1/00

(52) U.S. Cl. CPC G01R 31/085; H02H 7/268; H02H 1/0007

(57) ABSTRACT

The invention discloses a commutation failure protection method, and apparatus, computer device and storage medium thereof. The method comprises: collecting three-phase AC currents on a valve-side of a converter, a DC current on a high-voltage side and a DC current on a neutral terminal; selecting a minimum value of an absolute value of the three-phase AC currents on the valve side as an AC characteristic quantity, and selecting a maximum value of the DC current on the high-voltage side and the DC current on the neutral terminal as a DC characteristic quantity; according to the AC characteristic quantity and the DC characteristic quantity, constructing a minimum characteristic quantity; comparing the minimum characteristic quantity with a first preset threshold, and outputting a commutation judgment result; according to the commutation judgment result, constructing a commutation time interval; comparing the commutation time interval with a second preset threshold and a third preset threshold, and outputting a commutation failure protection judgment result to determine whether a commutation failure occurs. The invention uses minimum current sequence characteristics to track a commutation process of a converter valve, and when a commutation failure occurs, it may make timely, accurate and reliable judgment, thereby ensuring safe operation of valve equipment.

### TECHNICAL FIELD

The invention relates to a commutation failure protection method, and apparatus, computer device and storage medium thereof, and belongs to the technical field of high-voltage direct current transmission.

### TECHNICAL BACKGROUND

AC fault not only affects the normal operation of an AC system, but also causes the commutation failure of a high-voltage DC transmission system, which in turn endangers the safe and reliable operation of a converter valve. Therefore, it is necessary to configure the corresponding protection. At present, commutation failure protection of a DC transmission system uses a maximum value of three-phase valve currents and the DC current as the AC and DC characteristic quantities, and the differential current of the AC and DC characteristic quantities is used to determine whether a commutation failure has occurred. This is to use amplitude characteristics of electrical quantities to indirectly determine a commutation failure, which will inevitably be affected by factors such as system operation mode, fault type, and fault severity etc. It has insufficient sensitivity, rapidity, and reliability. It is necessary to start with the commutation process itself, and carry out timely, reliable and accurate tracking of the commutation process to improve the sensitivity and accuracy of a judgment of the commutation failure.

### SUMMARY OF THE INVENTION

In view of this, the present invention provides a commutation failure protection method, apparatus, computer device and storage medium thereof, which uses minimum current sequence characteristics to track a commutation process of a converter valve. When a commutation failure occurs, a timely, accurate and reliable judgment may be made to ensure the safe operation of valve equipment.

The first objective of the present invention is to provide a commutation failure protection method.

The second objective of the present invention is to provide a commutation failure protection apparatus.

The third objective of the present invention is to provide a computer device.

The fourth objective of the present invention is to provide a storage medium.

The first objective of the present invention may be achieved by adopting the following technical solutions:

A commutation failure protection method applied to a high-voltage DC transmission system, the method comprises:

collecting three-phase AC currents on a valve-side of a converter, a DC current on a high-voltage side and a DC current on a neutral terminal;

selecting a minimum value of an absolute value of the three-phase AC currents on the valve-side as an AC characteristic quantity, and selecting a maximum value of the DC current on the high-voltage side and the DC current on the neutral terminal as a DC characteristic quantity;

according to the AC characteristic quantity and the DC characteristic quantity, constructing a minimum characteristic quantity;

comparing the minimum characteristic quantity with a first preset threshold, and outputting a commutation judgment result;

according to the commutation judgment result, constructing a commutation time interval;

comparing the commutation time interval with a second preset threshold and a third preset threshold, and outputting a commutation failure protection determination result to determine whether a commutation failure occurs; wherein the third preset threshold is greater than the second preset threshold.

Further, the step of selecting a minimum value of an absolute value of the three-phase AC currents on the valve-side as an AC characteristic quantity, and selecting a maximum value of the DC current on the high-voltage side and the DC current on the neutral terminal as a DC characteristic quantity, specifically comprises:

selecting the minimum value of the absolute value of the three-phase AC currents on the valve side as the AC characteristic quantity using the following formula:

i_{ac min}=Min(|iₐ|,|i_{b}|,|i_{c}|)

wherein iₐ, i_{b}, i_{c} represent the three-phase AC currents on the valve-side, |iₐ|, |i_{b}|, |i_{c}| represent the absolute values of the three-phase AC currents on the valve side, and Min(|iₐ|,|i_{b}|,|i_{c}|) represent the minimum value of the absolute value of the three-phase AC currents on the valve side;

selecting the maximum value of the DC current on the high-voltage side and the DC current on the neutral terminal as the DC characteristic quantity using the following formula:

i_{d max}=Max(i_{dN},i_{dH})

wherein, i_{dH} represents the DC current on the high-voltage side, i_{dN} represents the DC current on the neutral terminal, and max(i_{dN},i_{dH}) represents the maximum value of the DC current on the high-voltage side and the DC current on the neutral terminal.

Further, the step of according to the AC characteristic quantity and the DC characteristic quantity, constructing a minimum characteristic quantity uses the following formula:

$${k}_{min} = \frac{{i}_{ac min}}{{i}_{d max}} = \frac{Min ( \vert {i}_{a} \vert , \vert {i}_{b} \vert , \vert {i}_{c} \vert )}{Max ( {i}_{dN} , {i}_{dH} )}$$

wherein i_{ac min} represents the AC characteristic quantity, and i_{d max} represents the DC characteristic quantity.

Further, the step of comparing the minimum characteristic quantity with a first preset threshold, and outputting a commutation judgment result uses the following formula:

$$\{ \begin{matrix}{p}_{0} = 1 , {k}_{min} \geq {k}_{set 0} \\ {p}_{0} = 0 , {k}_{min} < {k}_{set 0}\end{matrix}$$

wherein p₀ represents the commutation judgment result; kₘᵢₙ is compared with the first preset threshold k_{set 0} to output the commutation judgment result; when p₀=1, there is a commutation, and when p₀=0, there is no commutation.

Further, the step of according to the commutation judgment result, constructing a commutation time interval, specifically comprises:

using the commutation judgment result to integrate within a set time value to construct the commutation time interval:

$${p}_{t} = {\int }_{t - {t}_{set}}^{t} {p}_{0} d t$$

wherein tₛₑₜ represents the set time value, pₜ represents the commutation time interval.

Further, a setting of the set time value is as follows:

$${t}_{set} = \frac{T}{6}$$

wherein

$$\frac{T}{6}$$

represents a conduction time interval of each converter valve, and T represents a power frequency cycle.

Further, the step of comparing the commutation time interval with a second preset threshold and a third preset threshold, and outputting a commutation failure protection judgment result to determine whether a commutation failure occurs uses the following formula:

$$\{ \begin{matrix}{p}_{1} = 1 , & {k}_{set 1} \leq {p}_{t} \leq {k}_{set 2} \\ {p}_{1} = 0 , & {p}_{t} < {k}_{set 1} or {p}_{t} > {k}_{set 2}\end{matrix}$$

wherein p₁ represents the commutation time interval; pₜ is compared with the second preset threshold k_{set 1} and the third preset threshold k_{set 2} to output the commutation failure protection determination result; when p₁=1, commutation is normal, when p₁=0, commutation failure occurs.

The second objective of the present invention may be achieved by adopting the following technical solutions:

A commutation failure protection apparatus applied to a high-voltage DC transmission system, the apparatus comprises:

a collecting module used to collect three-phase AC currents on a valve-side of a converter, a DC current on a high-voltage side and a DC current on a neutral terminal;

a selecting module used to select a minimum value of an absolute value of the three-phase AC currents on the valve-side as an AC characteristic quantity, and selecting a maximum value of the DC current on the high-voltage side and the DC current on the neutral terminal as a DC characteristic quantity;

a first constructing module used to construct a minimum characteristic quantity according to the AC characteristic quantity and the DC characteristic quantity;

a first comparing module used to compare the minimum characteristic quantity with a first preset threshold, and outputting a commutation judgment result;

a second constructing module used to construct a commutation time interval according to the commutation judgment result;

a second comparing module used to compare the commutation time interval with a second preset threshold and a third preset threshold, and outputting a commutation failure protection determination result to determine whether a commutation failure occurs; wherein the third preset threshold is greater than the second preset threshold.

The third objective of the present invention may be achieved by adopting the following technical solutions:

A computer device comprising a processor and a memory for storing an executable program for the processor, when the processor executes the program stored in the memory, the above commutation failure protection method is implemented.

The fourth objective of the present invention may be achieved by adopting the following technical solutions:

A storage medium storing a program, when the program is executed by a processor, the above commutation failure protection method is implemented.

Compared with the current technology, the present invention has the following beneficial effects:

The present invention collects three-phase AC currents on a valve-side of a converter, a DC current on a high-voltage side and a DC current on a neutral terminal, and selects a minimum value of an absolute value of the three-phase AC currents on the valve-side as an AC characteristic quantity, and selecting a maximum value of the DC current on the high-voltage side and the DC current on the neutral terminal as a DC characteristic quantity to construct a minimum characteristic quantity. By tracking a commutation process through the minimum characteristic quantity, a commutation judgment result is output, reflecting the commutation state of the converter valve in time, and constructing a commutation time interval, and realizing accurate, sensitive and quick commutation failure protection through the commutation time interval.

### DESCRIPTION OF THE FIGURES

In order to explain the embodiments of the present invention or the technical solutions in the prior art more clearly, the following will briefly introduce the figures that are used in the description of the embodiments or the current technology. It can be seen that the figures in the following description are for only some embodiments of the present invention. For those of ordinary skilled in the art, without inventive work, other figures may be obtained based on the structure shown in these figures.

FIG. 1 is a flowchart of a commutation failure protection method according to Embodiment 1 of the present invention.

FIG. 2 is a logic diagram of a commutation failure protection method according to Embodiment 1 of the present invention

FIG. 3 is a schematic diagram of a converter valve of a high-voltage DC power transmission system according to Embodiment 1 of the present invention

FIG. 4 is a waveform diagram of three-phase AC currents on a valve side of a converter, a DC current on a high-voltage side and a DC current on a neutral terminal according to Embodiment 1 of the present invention.

FIG. 5 is a waveform diagram of an AC characteristic quantity and the DC characteristic quantity according to Embodiment 1 of the present invention.

FIG. 6 is a waveform diagram of the minimum characteristic quantity according to Embodiment 1 of the present invention.

FIG. 7 is a waveform diagram of a commutation and protection judgment according to Embodiment 1 of the present invention.

FIG. 8 is a structural block diagram of a commutation failure protection apparatus according to Embodiment 2 of the present invention.

FIG. 9 is a structural block diagram of a computer device according to Embodiment 3 of the present invention.

### DESCRIPTION

In order to explain the objectives, technical solutions, and advantages of the embodiments of the present invention clearer, the technical solutions in the embodiments of the present invention will be described clearly and completely in conjunction with the accompanying figures in the embodiments of the present invention. Clearly, the described embodiments are parts of the embodiments of the present invention, not all of the embodiments. Based on the embodiments of the present invention, all other embodiments obtained by those of ordinary skilled in the art, without inventive work, shall fall within the protection scope of the present invention.

### Embodiment 1

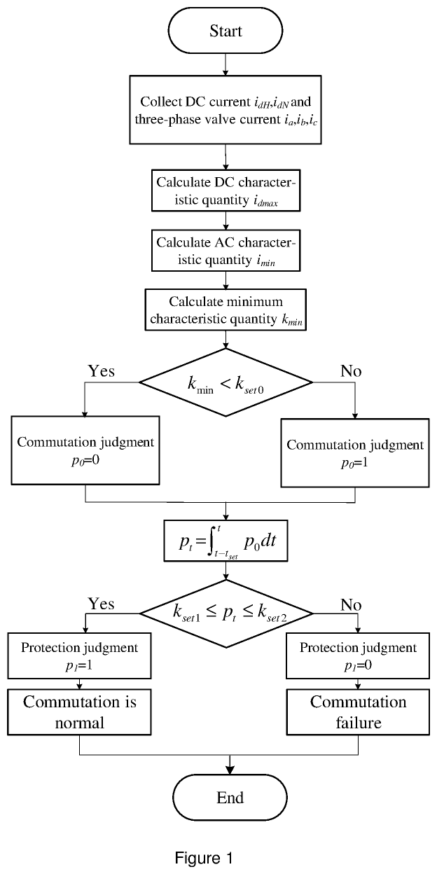

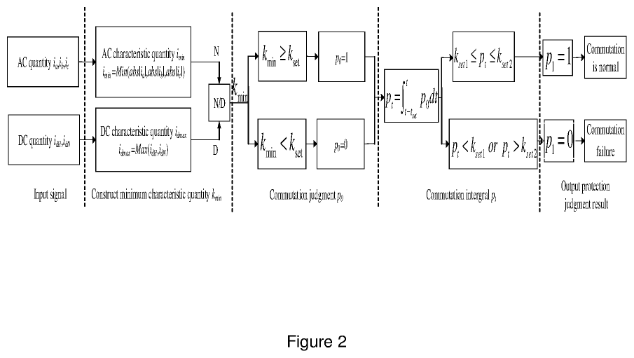

As shown in FIGS. 1 and 2, this embodiment provides a commutation failure protection method, which is applied to a high-voltage DC transmission system and comprises the following steps:

S1. collecting three-phase AC currents on a valve side of a converter, a DC current on a high-voltage side and a DC current on a neutral terminal.

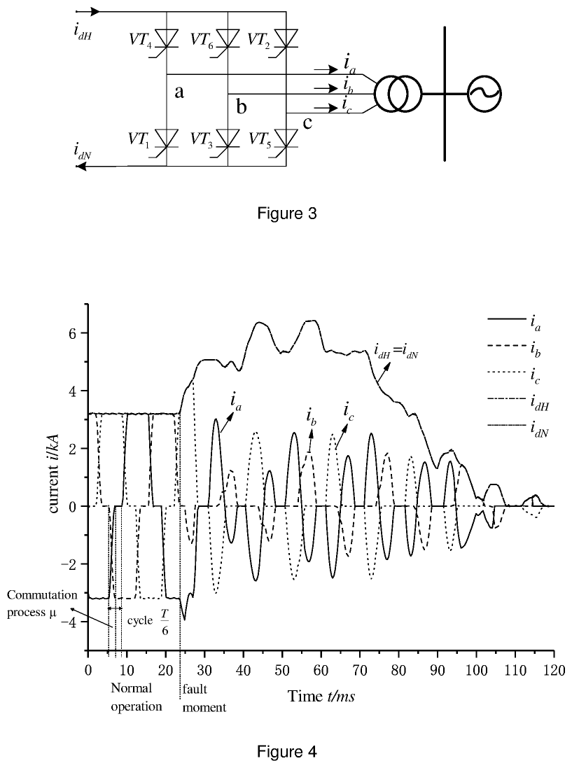

The converter valve structure of the high-voltage DC power transmission system of this embodiment is shown in FIG. 3, collecting the three-phase (a-phase, b-phase, and c-phase) AC currents, iₐ, i_{b}, i_{c}, the DC current i_{dH} on the high-voltage side and the DC current i_{dN} on the neutral terminal. The waveforms of the three-phase AC currents on a valve-side of a converter, the DC current on the high-voltage side and the DC current on the neutral terminal are shown in FIG. 4. In normal operation, the conduction time interval (conduction period) of each converter valve is

$$\frac{T}{6} ,$$

and the time interval of the commutation process is μ.

S2. selecting a minimum value of an absolute value of the three-phase AC currents on the valve-side as an AC characteristic quantity, and selecting a maximum value of the DC current on the high-voltage side and the DC current on the neutral terminal as a DC characteristic quantity.

S21. selecting the minimum value of the absolute value of the three-phase AC currents on the valve-side as the AC characteristic quantity i_{ac min} using the following formula:

i_{ac min}=Min(|iₐ|,|i_{b}|,|i_{c}|) (1)

wherein |iₐ|, |i_{b}|, |i_{c}| represent the absolute values of the three-phase AC currents on the valve side, and Min(|iₐ|,|i_{b}|,|i_{c}|) represent the minimum value of the absolute value of the three-phase AC currents on the valve-side.

S22. selecting the maximum value of the DC current on the high-voltage side and the DC current on the neutral terminal as the DC characteristic quantity i_{d max} using the following formula:

i_{d max}=Max(i_{dN},i_{dH}) (2)

wherein Max(i_{dN},i_{dH}) represents the maximum value of the DC current on the high-voltage side and the DC current on the neutral terminal.

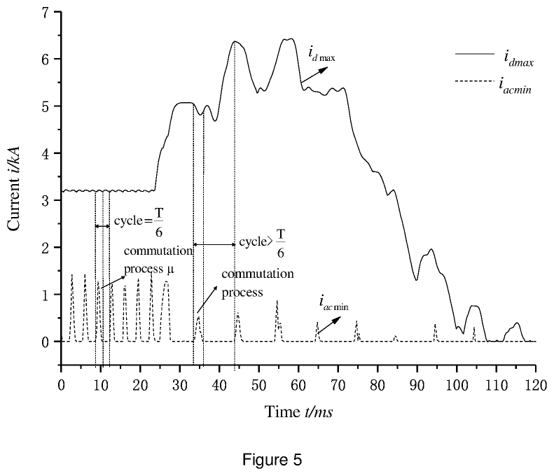

The waveforms of the selected AC characteristic quantity i_{ac min} and DC characteristic quantity i_{d max} are shown in FIG. 5

S3. according to the AC characteristic quantity and the DC characteristic quantity, constructing a minimum characteristic quantity.

Specifically, using a ratio between the AC characteristic quantity and the DC characteristic quantity, the minimum characteristic quantity kₘᵢₙ is constructed as follows:

$${k}_{min} = \frac{{i}_{ac min}}{{i}_{d max}} = \frac{Min ( \vert {i}_{a} \vert , \vert {i}_{b} \vert , \vert {i}_{c} \vert )}{Max ( {i}_{dN} , {i}_{dH} )} \qquad ( 3 )$$

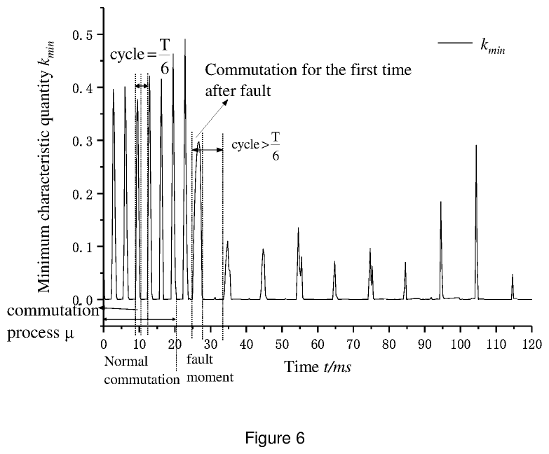

The waveform of the constructed minimum characteristic quantity kₘᵢₙ is shown in FIG. 6. In normal operation, the period of the minimum characteristic quantity kₘᵢₙ is

$$\frac{T}{6} ,$$

and corresponds to the conduction time interval of the converter valve. The sharp wave of the minimum characteristic quantity kₘᵢₙ corresponds to the time interval μ of the commutation process of the converter valve.

S4. comparing the minimum characteristic quantity with a first preset threshold, and outputting a commutation judgment result using the following formula:

$$\{ \begin{matrix}{p}_{0} = 1 , {k}_{min} \geq {k}_{set 0} \\ {p}_{0} = 0 , {k}_{min} < {k}_{set 0}\end{matrix} \qquad ( 4 )$$

wherein p₀ represents the commutation judgment result; kₘᵢₙ is compared with the first preset threshold k_{set 0} to output the commutation judgment result;

When kₘᵢₙ≥k_{set 0}, p₀ outputs high, that is p₀=1, and it means that there is a commutation (commutation is in progress); when kₘᵢₙ<k_{set 0}, p₀ outputs low, that is p₀=0, and it means that there is no commutation (non-commutation or commutation abnormality).

S5. according to the commutation judgment result, constructing a commutation time interval.

Since the minimum characteristic quantity kₘᵢₙ characterizes a commutation process, the period of the minimum characteristic quantity kₘᵢₙ corresponds to the conduction time interval of the converter valve. The non-zero period of the minimum characteristic quantity kₘᵢₙ corresponds to the commutation process interval of the converter valve; considering that the converter valve is under normal operation, the conduction time interval of each converter valve is

$$\frac{T}{6} ,$$

and the time interval of the commutation process is μ, so the set time value is set as follows:

$${t}_{set} = \frac{T}{6} \qquad ( 5 )$$

wherein T represents a power frequency cycle, and its value is 20 ms.

Using the commutation judgment result p₀ to integrate within a set time value tₛₑₜ to construct the commutation time interval pₜ,

$${p}_{t} = {\int }_{t - {t}_{set}}^{t} {p}_{0} d t \qquad ( 6 )$$

S6. comparing the commutation time interval with a second preset threshold and a third preset threshold, and outputting a commutation failure protection judgment result to determine whether a commutation failure occurs using the following formula:

$$\{ \begin{matrix}{p}_{1} = 1 , & {k}_{set 1} \leq {p}_{t} \leq {k}_{set 2} \\ {p}_{1} = 0 , & {p}_{t} < {k}_{set 1} or {p}_{t} > {k}_{set 2}\end{matrix} \qquad ( 7 )$$

wherein, p₁ represents the output commutation failure protection judgment result by comparing the commutation time interval with the second preset threshold k_{set 1} and the third preset threshold k_{set 2}, and the third preset threshold k_{set 2} is greater than the second preset threshold k_{set 1}.

When k_{set 1}≤pₜ≤k_{set 2}, p₁ outputs high, that is p₁=1, and it means that the commutation is normal; when pₜ<k_{set 1} or pₜ>k_{set 2}, p₁ outputs low, that is p₁=0, and it means that the commutation has failed.

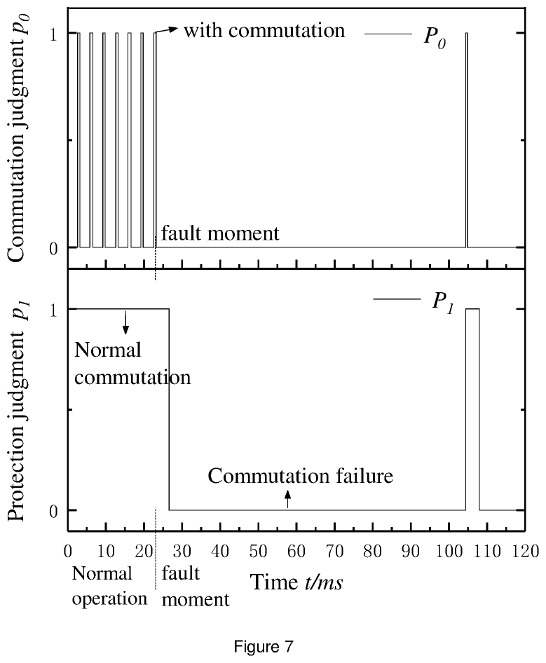

In the above steps S4 and S6, the outputs of p₀ and p₁ are as shown in FIG. 7.

Those skilled in the art can understand that all or parts of the steps in the method for implementing the above-mentioned embodiments may be completed by instructing relevant hardware through a program, and the corresponding program may be stored in a computer-readable storage medium.

It should be noted that although the method operations of the foregoing embodiments are described in a specific order in the figures, this does not require or imply that these operations must be performed in the specific order, or that all the operations shown must be performed to achieve the desired results. Conversely, the depicted steps can change the order of execution. Additionally or alternatively, some steps may be omitted, multiple steps may be combined into one step for execution, and/or one step may be decomposed into multiple steps for execution.

### Embodiment 2

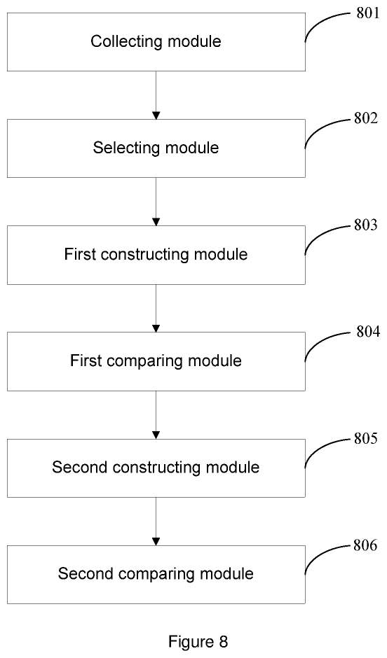

As shown in FIG. 8, this embodiment provides a commutation failure protection apparatus, which is applied to a high-voltage DC transmission system. It comprises a collection module 801, a selection module 802, a first construction module 803, a first comparison module 804, a second construction module 805 and a second comparison module 806. The specific functions of each module are as follows:

The collecting module 801 is used to collect three-phase AC currents on a valve-side of a converter, a DC current on a high-voltage side and a DC current on a neutral terminal.

The selecting module 802 is used to select a minimum value of an absolute value of the three-phase AC currents on the valve-side as an AC characteristic quantity, and selecting a maximum value of the DC current on the high-voltage side and the DC current on the neutral terminal as a DC characteristic quantity.

The first constructing module 803 is used to construct a minimum characteristic quantity according to the AC characteristic quantity and the DC characteristic quantity.

The first comparing module 804 is used to compare the minimum characteristic quantity with a first preset threshold, and outputting a commutation judgment result.

The second constructing module 805 is used to construct a commutation time interval according to the commutation judgment result.

The second comparing module 806 is used to compare the commutation time interval with a second preset threshold and a third preset threshold, and outputting a commutation failure protection judgment result to determine whether a commutation failure occurs; wherein the third preset threshold is greater than the second preset threshold.

The specific implementation of each module in this embodiment can be found in the above Embodiment 1, which will not be repeated here. It should be noted that the system provided in this embodiment only uses the division of the above functional modules for illustration. In practice, the above-mentioned function allocation may be completed by different functional modules according to needs, that is, the internal structure is divided into different function modules to complete all or parts of the functions described above.

### Embodiment 3

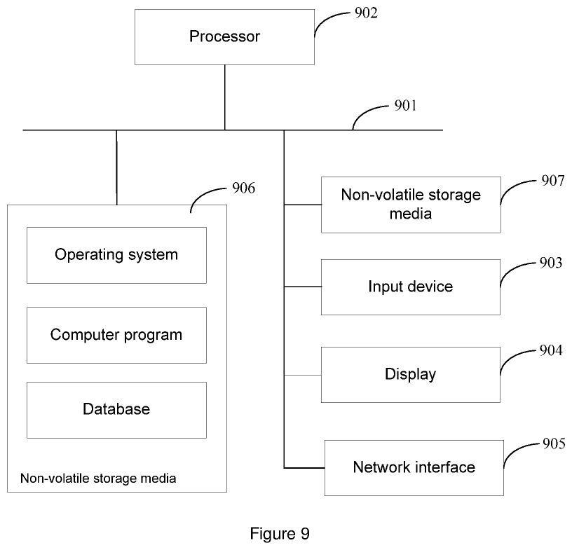

This embodiment provides a computer device, which is a computer. As shown in FIG. 9, it comprises a processor 902, a memory, an input device 903, a display 904, and a network interface 905 connected by a system bus 901. The processor is used to provide computing and control capabilities. The memory comprises a non-volatile storage medium 906 and an internal memory 907. The non-volatile storage medium 906 stores an operating system, a computer program, and a database. The internal memory 907 provides an environment for the operation of the operating system and the computer program in the non-volatile storage medium. When the processor 902 executes the computer program stored in the memory, the commutation failure protection method of the above Embodiment 1 is implemented as follows:

collecting three-phase AC currents on a valve side of a converter, a DC current on a high-voltage side and a DC current on a neutral terminal;

selecting a minimum value of an absolute value of the three-phase AC currents on the valve side as an AC characteristic quantity, and selecting a maximum value of the DC current on the high-voltage side and the DC current on the neutral terminal as a DC characteristic quantity;

according to the AC characteristic quantity and the DC characteristic quantity, constructing a minimum characteristic quantity;

comparing the minimum characteristic quantity with a first preset threshold, and outputting a commutation judgment result;

according to the commutation judgment result, constructing a commutation time interval;

comparing the commutation time interval with a second preset threshold and a third preset threshold, and outputting a commutation failure protection judgment result to determine whether a commutation failure occurs; wherein the third preset threshold is greater than the second preset threshold.

### Embodiment 4

This embodiment provides a storage medium, which is a computer-readable storage medium that stores a computer program, and when the computer program is executed by a processor, the commutation failure protection method of the above Embodiment 1 is implemented as follows:

collecting three-phase AC currents on a valve-side of a converter, a DC current on a high-voltage side and a DC current on a neutral terminal;

selecting a minimum value of an absolute value of the three-phase AC currents on the valve-side as an AC characteristic quantity, and selecting a maximum value of the DC current on the high-voltage side and the DC current on the neutral terminal as a DC characteristic quantity;

according to the AC characteristic quantity and the DC characteristic quantity, constructing a minimum characteristic quantity;

comparing the minimum characteristic quantity with a first preset threshold, and outputting a commutation judgment result;

according to the commutation judgment result, constructing a commutation time interval;

comparing the commutation time interval with a second preset threshold and a third preset threshold, and outputting a commutation failure protection judgment result to determine whether a commutation failure occurs; wherein the third preset threshold is greater than the second preset threshold.

The storage medium described in this embodiment may be a magnetic disk, an optical disk, a computer memory, a random access memory (RAM), a USB flash drive, a mobile hard disk, and other media.

In summary, the present invention collects three-phase AC currents on a valve-side of a converter, a DC current on a high-voltage side and a DC current on a neutral terminal, and selects a minimum value of an absolute value of the three-phase AC currents on the valve-side as an AC characteristic quantity, and selecting a maximum value of the DC current on the high-voltage side and the DC current on the neutral terminal as a DC characteristic quantity to construct a minimum characteristic quantity. By tracking a commutation process through the minimum characteristic quantity, a commutation judgment result is output, reflecting the commutation state of the converter valve in time, and constructing a commutation time interval, and realizing accurate, sensitive and quick commutation failure protection through the commutation time interval.

The above are only the preferred embodiments of the present invention patent, but the scope of protection of the present invention patent is not limited to this. Anything that does not deviate from the equivalent implementation or changes of the present invention patent using the relative relationship between AC and DC and the timing structure of commutation failure protection, including diagrams, formulas, preset thresholds etc., all belong to the scope of protection of the present invention patent.

1. A commutation failure protection method applied to a high-voltage DC transmission system, characterized in that, the method comprises:
collecting three-phase AC currents on a valve-side of a converter, a DC current on a high-voltage side and a DC current on a neutral terminal;
selecting a minimum value of an absolute value of the three-phase AC currents on the valve-side as an AC characteristic quantity, and selecting a maximum value of the DC current on the high-voltage side and the DC current on the neutral terminal as a DC characteristic quantity;
according to the AC characteristic quantity and the DC characteristic quantity, constructing a minimum characteristic quantity;
comparing the minimum characteristic quantity with a first preset threshold, and outputting a commutation judgment result;
according to the commutation judgment result, constructing a commutation time interval;
comparing the commutation time interval with a second preset threshold and a third preset threshold, and outputting a commutation failure protection judgment result to determine whether a commutation failure occurs; wherein the third preset threshold is greater than the second preset threshold.

2. The commutation failure protection method according to claim 1, characterized in that, the step of selecting a minimum value of an absolute value of the three-phase AC currents on the valve-side as an AC characteristic quantity, and selecting a maximum value of the DC current on the high-voltage side and the DC current on the neutral terminal as a DC characteristic quantity, comprises:
selecting the minimum value of the absolute value of the three-phase AC currents on the valve-side as the AC characteristic quantity using the following formula:
i_{ac min}=Min(|iₐ|,|i_{b}|,|i_{c}|)
wherein iₐ, i_{b}, i_{c} represent the three-phase AC currents on the valve-side, |iₐ|, |i_{b}|, |i_{c}| represent the absolute values of the three-phase AC currents on the valve-side, and Min(|iₐ|,|i_{b}|,|i_{c}|) represent the minimum value of the absolute value of the three-phase AC currents on the valve-side;
selecting the maximum value of the DC current on the high-voltage side and the DC current on the neutral terminal as the DC characteristic quantity using the following formula:
i_{d max}=Max(i_{dN},i_{dH})
wherein, i_{dH} represents the DC current on the high-voltage side, i_{dN} represents the DC current at the neutral terminal, and Max(i_{dN},i_{dH}) represents the maximum value of the DC current on the high-voltage side and the DC current on the neutral terminal.

3. The commutation failure protection method according to claim 2, characterized in that, the step of according to the AC characteristic quantity and the DC characteristic quantity, constructing a minimum characteristic quantity uses the following formula:
$${k}_{min} = \frac{{i}_{ac min}}{{i}_{d max}} = \frac{Min ( \vert {i}_{a} \vert , \vert {i}_{b} \vert , \vert {i}_{c} \vert )}{Max ( {i}_{dN} , {i}_{dH} )}$$
wherein i_{ac min} represents the AC characteristic quantity, and i_{d max} represents the DC characteristic quantity.

4. The commutation failure protection method according to claim 1, characterized in that, the step of comparing the minimum characteristic quantity with a first preset threshold, and outputting a commutation judgment result uses the following formula:
$$\{ \begin{matrix}{p}_{0} = 1 , {k}_{min} \geq {k}_{set 0} \\ {p}_{0} = 0 , {k}_{min} < {k}_{set 0}\end{matrix}$$
wherein p₀ represents the commutation judgment result; kₘᵢₙ is compared with the first preset threshold k_{set 0} to output the commutation judgment result; when p₀=1, there is a commutation, and when p₀=0, there is no commutation.

5. The commutation failure protection method according to claim 4, characterized in that, the step of according to the commutation judgment result, constructing a commutation time interval, comprises:
using the commutation judgment result to integrate within a set time value to construct the commutation time interval,
$${p}_{t} = {\int }_{t - {t}_{set}}^{t} {p}_{0} d t$$
wherein tₛₑₜ represents the set time value, pₜ represents the commutation time interval.

6. The commutation failure protection method according to claim 5, characterized in that, a setting of the set time value is as follows:
$${t}_{s e t} = \frac{T}{6}$$
wherein
$$\frac{T}{6}$$
represents a conduction time interval of each converter valve, and T represents a power frequency cycle.

7. The commutation failure protection method according to claim 1, characterized in that, the step of comparing the commutation time interval with a second preset threshold and a third preset threshold, and outputting a commutation failure protection judgment result to determine whether a commutation failure occurs uses the following formula:
$$\{ \begin{matrix}{p}_{1} = 1 , {k}_{set 1} \leq {p}_{t} \leq {k}_{s e t 2} \\ {p}_{1} = 0 , {p}_{t} < {k}_{s e t 1} or {p}_{t} > {k}_{s e t 2}\end{matrix}$$
wherein p₁ represents the commutation time interval; pₜ is compared with the second preset threshold k_{set 1} and the third preset threshold k_{set 2} to output the commutation failure protection judgment result; when p₁=1, commutation is normal, when p₁=0, commutation failed.

8. A commutation failure protection apparatus applied to a high-voltage DC transmission system, characterized in that, the apparatus comprises:
a collecting module used to collect three-phase AC currents on a valve-side of a converter, a DC current on a high-voltage side and a DC current on a neutral terminal;
a selecting module used to select a minimum value of an absolute value of the three-phase AC currents on the valve: side as an AC characteristic quantity, and selecting a maximum value of the DC current on the high-voltage side and the DC current on the neutral terminal as a DC characteristic quantity;
a first constructing module used to construct a minimum characteristic quantity according to the AC characteristic quantity and the DC characteristic quantity;
a first comparing module used to compare the minimum characteristic quantity with a first preset threshold, and outputting a commutation judgment result;
a second constructing module used to construct a commutation time interval according to the commutation judgment result;
a second comparing module used to compare the commutation time interval with a second preset threshold and a third preset threshold, and outputting a commutation failure protection judgment result to determine whether a commutation failure occurs;
wherein the third preset threshold is greater than the second preset threshold.

9. A computer device comprising a processor and a memory for storing an executable program for the processor, characterized in that, when the processor executes the program stored in the memory, a commutation failure protection method is implemented that comprises:
collecting three-phase AC currents on a valve-side of a converter, a DC current on a high-voltage side and a DC current on a neutral terminal;
selecting a minimum value of an absolute value of the three-phase AC currents on the valve-side as an AC characteristic quantity, and selecting a maximum value of the DC current on the high-voltage side and the DC current on the neutral terminal as a DC characteristic quantity;
according to the AC characteristic quantity and the DC characteristic quantity, constructing a minimum characteristic quantity;
comparing the minimum characteristic quantity with a first preset threshold, and outputting a commutation judgment result;
according to the commutation judgment result, constructing a commutation time interval;
comparing the commutation time interval with a second preset threshold and a third preset threshold, and outputting a commutation failure protection judgment result to determine whether a commutation failure occurs; wherein the third preset threshold is greater than the second preset threshold.

10. A storage medium storing a program, characterized in that, when the program is executed by a processor, the commutation failure protection method according to claim 1 is implemented.

11. The commutation failure protection method according to claim 2, characterized in that, the step of comparing the minimum characteristic quantity with a first preset threshold, and outputting a commutation judgment result uses the following formula:
$$\{ \begin{matrix}{p}_{0} = 1 , {k}_{min} \geq {k}_{set 0} \\ {p}_{0} = 0 , {k}_{min} < {k}_{set 0}\end{matrix}$$
wherein p₀ represents the commutation judgment result; kₘᵢₙ is compared with the first preset threshold k_{set 0} to output the commutation judgment result; when p₀=1, there is a commutation, and when p₀=0, there is no commutation.

12. The commutation failure protection method according to claim 3, characterized in that, the step of comparing the minimum characteristic quantity with a first preset threshold, and outputting a commutation judgment result uses the following formula:
$$\{ \begin{matrix}{p}_{0} = 1 , {k}_{min} \geq {k}_{set 0} \\ {p}_{0} = 0 , {k}_{min} < {k}_{set 0}\end{matrix}$$
wherein p₀ represents the commutation judgment result; kₘᵢₙ is compared with the first preset threshold k_{set 0} to output the commutation judgment result; when p₀=1, there is a commutation, and when p₀=0, there is no commutation.

13. The commutation failure protection method according to claim 2, characterized in that, the step of comparing the commutation time interval with a second preset threshold and a third preset threshold, and outputting a commutation failure protection judgment result to determine whether a commutation failure occurs uses the following formula:
$$\{ \begin{matrix}{p}_{1} = 1 , {k}_{set 1} \leq {p}_{t} \leq {k}_{s e t 2} \\ {p}_{1} = 0 , {p}_{t} < {k}_{s e t 1} or {p}_{t} > {k}_{s e t 2}\end{matrix}$$
wherein p₁ represents the commutation time interval; pₜ is compared with the second preset threshold k_{set 1} and the third preset threshold k_{set 2} to output the commutation failure protection judgment result; when p₁=1, commutation is normal, when p₁=0, commutation failed.

14. The commutation failure protection method according to claim 3, characterized in that, the step of comparing the commutation time interval with a second preset threshold and a third preset threshold, and outputting a commutation failure protection judgment result to determine whether a commutation failure occurs uses the following formula:
$$\{ \begin{matrix}{p}_{1} = 1 , {k}_{set 1} \leq {p}_{t} \leq {k}_{s e t 2} \\ {p}_{1} = 0 , {p}_{t} < {k}_{s e t 1} or {p}_{t} > {k}_{s e t 2}\end{matrix}$$
wherein p₁ represents the commutation time interval; pₜ is compared with the second preset threshold k_{set 1} and the third preset threshold k_{set 2} to output the commutation failure protection judgment result; when p₁=1, commutation is normal, when p₁=0, commutation failed.

15. The computer device according to claim 9, characterized in that, the step of selecting a minimum value of an absolute value of the three-phase AC currents on the valve-side as an AC characteristic quantity, and selecting a maximum value of the DC current on the high-voltage side and the DC current on the neutral terminal as a DC characteristic quantity, comprises:
selecting the minimum value of the absolute value of the three-phase AC currents on the valve-side as the AC characteristic quantity using the following formula:
i_{ac min}=Min(|iₐ|,|i_{b}|,|i_{c}|)
wherein iₐ, i_{b}, i_{c} represent the three-phase AC currents on the valve-side, |iₐ|,|i_{b}|,|i_{c}| represent the absolute values of the three-phase AC currents on the valve-side, and min(|iₐ|,|i_{b}|,|i_{c}|) represent the minimum value of the absolute value of the three-phase AC currents on the valve-side;
selecting the maximum value of the DC current on the high-voltage side and the DC current on the neutral terminal as the DC characteristic quantity using the following formula:
i_{d max}=Max(i_{dN},i_{dH})
wherein, i_{dH} represents the DC current on the high-voltage side, i_{dN} represents the DC current at the neutral terminal, and Max(i_{dN},i_{dH}) represents the maximum value of the DC current on the high-voltage side and the DC current on the neutral terminal.

16. The computer device according to claim 9, characterized in that, the step of according to the AC characteristic quantity and the DC characteristic quantity, constructing a minimum characteristic quantity uses the following formula:
$${k}_{min} = \frac{{i}_{ac min}}{{i}_{dmax}} = \frac{Min ( \vert {i}_{a} \vert , \vert {i}_{b} \vert , \vert {i}_{c} \vert )}{Max ( {i}_{d N} , {i}_{d H} )}$$
wherein i_{ac min} represents the AC characteristic quantity, and i_{d max} represents the DC characteristic quantity.

17. The computer device of claim 9, characterized in that, the step of comparing the minimum characteristic quantity with a first preset threshold, and outputting a commutation judgment result uses the following formula:
$$\{ \begin{matrix}{p}_{0} = 1 , {k}_{min} \geq {k}_{set 0} \\ {p}_{0} = 0 , {k}_{min} < {k}_{set 0}\end{matrix}$$
wherein p₀ represents the commutation judgment result; kₘᵢₙ is compared with the first preset threshold k_{set 0} to output the commutation judgment result; when p₀=1, there is a commutation, and when p₀=0, there is no commutation.

18. The computer device of claim 17, characterized in that, the step of according to the commutation judgment result, constructing a commutation time interval, comprises:
using the commutation judgment result to integrate within a set time value to construct the commutation time interval,
$${p}_{t} = {\int }_{t - {t}_{set}}^{t} {p}_{0} d t$$
wherein tₛₑₜ represents the set time value, pₜ represents the commutation time interval.

19. The computer device according to claim 18, characterized in that, a setting of the set time value is as follows:
$${t}_{s e t} = \frac{T}{6}$$
wherein
$$\frac{T}{6}$$
represents a conduction time interval of each converter valve, and T represents a power frequency cycle.

20. The computer device of claim 9, characterized in that, the step of comparing the commutation time interval with a second preset threshold and a third preset threshold, and outputting a commutation failure protection judgment result to determine whether a commutation failure occurs uses the following formula:
$$\{ \begin{matrix}{p}_{1} = 1 , {k}_{set 1} \leq {p}_{t} \leq {k}_{s e t 2} \\ {p}_{1} = 0 , {p}_{t} < {k}_{s e t 1} or {p}_{t} > {k}_{s e t 2}\end{matrix}$$
wherein p₁ represents the commutation time interval; pₜ is compared with the second preset threshold k_{set 1} and the third preset threshold k_{set 2} to output the commutation failure protection judgment result; when p₁=1, commutation is normal, when p₁=0, commutation failed.
